(19) United States
(12) Patent Application Publication
(10) Pub. No.: US 2011/0140253 A1
(43) Pub. Date: Jun. 16, 2011

(54) DAP GROUND BOND ENHANCEMENT

(75) Inventors: Shaw Wei LEE, Cupertino, CA (US); Yee Kim LEE, Segamat (MY); Ein Sun NG, Simpang Ampat (MY); Lee Han Meng @ Eugene LEE, Muar (MY); Ting Soon Peter CHIN, Melaka (MY)

(73) Assignee: NATIONAL SEMICONDUCTOR CORPORATION, Santa Clara, CA (US)

(21) Appl. No.: 12/637,657

(22) Filed: Dec. 14, 2009

(51) Int. Cl. H01L 23/495; H01L 21/60

(52) U.S. Cl. 257/676; 438/123; 257/E23.037; 257/E21.506

(57) ABSTRACT

A variety of semiconductor package arrangements and packaging methods are described that improve the reliability of bonding wires that down bond a die to a die attach pad. In one aspect, selected portions of the top surface of a lead frame (which may be in panel form) are plated (e.g., silver plated) to facilitate wire bonding. The plating covers some, but not all of a die attach surface of the die attach pad. In some preferred embodiments, the plating on the die attach pad is arranged as a peripheral ring that surrounds an unplated central region of the die support surface. In other embodiments, the plating on the die attach pad takes the form of bars or other geometric patterns that do not fully cover the die support surface. Unplated portions of the die support surface are roughened to improve the adherence of the die to the die attach pad, thereby reducing the probability of die attach pad delamination and the associated risks to down bonded bonding wires. The described lead frames may be used in a variety of packages. Most commonly, a die is attached to the die support surface of the die attach pad and electrically connected to the lead frame leads by wire bonding as appropriate. At least one of the die's bond pads (typically the ground bond pad(s)) is down bonded to the die attach pad. The die, the bonding wires and at least portions of the lead frame are then typically encapsulated with a plastic encapsulant material while leaving a contact surface of the die attach pad exposed to facilitate electrically coupling the die attach pad to an external device.

### BACKGROUND OF THE INVENTION

The present invention relates generally to lead frame based semiconductor packages. More particularly, arrangements that enhance the reliability of bonding wires electrically coupled to a die attach pad are described.

Many semiconductor packages utilize a metal lead frame to provide electrical interconnects between an integrated circuit die and external components. Very small electrical wires referred to as “bonding wires” are often used to electrically connect I/O pads (frequently referred to as “bond pad”) on the die to corresponding leads in the lead frame. Typically, the die, the bonding wires and portions of the lead frame are encapsulated in plastic for protection, while leaving portions of the lead frame exposed to facilitate electrical connection to external devices.

Many lead frames include a die attach pad (DAP) that supports the die during assembly of the package. In some packages, the die attach pad is exposed on a surface of the package (typically the bottom surface). An exposed die attach pad can help with the thermal management of the package because the die attach pad provides a good thermal conduction path for dissipating excess heat generated by the die. In some exposed DAP packages, the die attach pad is also used as an electrical contact for the package. Most commonly, the die attach pad is used as the ground pad, although in a few packages it may be used as a power pad and theoretically it could alternatively be used as a signal pad.

In some applications, as for example when the die attach pad is used as an electrical contact, bonding wires are used to electrically connect one or more ground I/O pads on the die to the die attach pad (a process frequently referred to as “down bonding”). Most commonly, very fine gold wires are used as the bonding wires and the lead frame is formed from copper or a copper based alloy. Since gold does not adhere well to copper, the die attach pad (and other relevant portions of the lead frame) are typically plated with a thin film of silver which adheres much better than copper to the gold bonding wires. A problem that occasionally occurs is that the die will sometimes delaminate from the die attach pad during use of the device. When die attach pad delamination occurs, movement of the die relative to the die attach pad can sometimes detach the down bonding wires from the die attach pad or otherwise break the down bonding wires.

Although existing down bonding techniques work well, there are continuing efforts to further improve down bonding reliability in a cost effective manner.

### SUMMARY OF THE INVENTION

A variety of semiconductor package arrangements and packaging methods are described that improve the reliability of bonding wires that down bond a die to a die attach pad. In one aspect, selected portions of the top surface of a lead frame (which may be in panel form), including portions (but not all) of the die attach pad, are plated (e.g., silver plated) to facilitate wire bonding. In some preferred embodiments, the plating on the die attach pad is arranged as a peripheral ring on that surrounds an open central region of the die support surface. In other embodiments, bars or other geometric patterns may be selectively plated on any desired and appropriate locations on the die attach pad. Unplated portions of the die support surface are roughened to improve the adherence of the die to the die attach pad and the molding compound to the die attach pad, thereby reducing the probability of die attach pad delamination and the associated risks to down bonded bonding wires. The described lead frames may be used in a variety of packages. Most commonly, a die is attached to the die support surface of the die attach pad and electrically connected to the lead frame leads by bonding wires as appropriate. At least one of the die's bond pads (typically the ground bond pad(s)) is down bonded to the die attach pad. The die, the bonding wires and at least portions of the lead frame are then typically encapsulated with a plastic encapsulant material while leaving a contact surface of the die attach pad exposed to facilitate electrically coupling the die attach pad to an external device.

The described lead frames may be used in a variety of packaging processes. Most commonly, a die is attached to the die support surface of the die attach pad and electrically connected to the lead frame leads by wire bonding as appropriate. At least one of the die's bond pads (typically the ground bond pad(s)) is down bonded to the die attach pad. The die, the bonding wires and at least portions of the lead frame are then typically encapsulated with a plastic encapsulant material. In exposed die attach pad packages, a contact surface of the die attach pad is left exposed to facilitate electrically coupling the die attach pad to an external device. When the die's ground pad(s) is/are down bonded to the die attach pad, the exposed die attach pad becomes the package's ground contact.

In various apparatus aspects of the present invention, a variety of novel package designs are described. In some embodiments, a die is mounted on a lead frame die attach pad. A first portion of the die attach pad is plated with a conductive plating material. A second, non-plated portion of the die attach pad is roughened in a manner that improves adhesion of the die to the die attach pad, thereby reducing the probability of the die delaminating from the die attach pad. In some preferred embodiments, the conductive plating is a silver based plating material formed as a ring that surrounds a roughened second portion of the die support surface. In other embodiments, bars of plating material may be formed at appropriate locations on the die attach pad. Selected bond pads on the die (typically ground pads) are down bonded to the plated portion of the die attach pad.

### BRIEF DESCRIPTION OF THE DRAWINGS

The invention and the advantages thereof, may best be understood by reference to the following description taken in conjunction with the accompanying drawings in which:

FIG. 1(a) is a diagrammatic top view of a lead frame panel having silver plated die attach pad rings in accordance with one embodiment of the present invention.

FIG. 1(b) is a diagrammatic top view of single device area in the lead frame panel illustrated in FIG. 1(a).

FIG. 2(a) is a flow chart illustrating a method of preparing a lead frame panel and packaging integrated circuit devices in accordance with one embodiment of the present invention.

FIG. 2(b) is a flow chart illustrating a method of preparing a lead frame panel and packaging integrated circuit devices in accordance with another embodiment of the present invention.

FIGS. 3(a)-3(g) are diagrammatic cross sectional views of a single device area illustrating several steps in the formation of the lead frame panel of FIG. 1 and the subsequent packaging of integrated circuits in accordance with the embodiment of the present invention illustrated in FIG. 2(a).

FIG. 4 is a diagrammatic cross sectional view of a singulated package formed in accordance with an embodiment of the present invention.

FIG. 5 is a diagrammatic top view of a single device area of a lead frame panel in accordance with another embodiment of the present invention that has multiple bars plated on the die attach pad.

In the drawings, like reference numerals are sometimes used to designate like structural elements. It should also be appreciated that the depictions in the figures are diagrammatic and not to scale.

### DETAILED DESCRIPTION OF THE PREFERRED EMBODIMENTS

The present invention relates generally to packaging methods and arrangements that enhance the reliability of bonding wires electrically coupled to a die attach pad. In general, selected portions of the top surface of a lead frame are plated to facilitate wire bonding. The plating covers some, but not all of a die attach surface of the die attach pad. In some preferred embodiments, the plating on the die attach pad is arranged as a peripheral ring that surrounds an unplated central region of the die support surface. In other embodiments, bars or other geometric plating patterns may be formed at suitable locations on the die attach pad. Unplated portions of the die support surface are roughened to improve the adherence of the die to the die attach pad, thereby reducing the probability of die attach pad delamination and the associated risks to down bonded bonding wires.

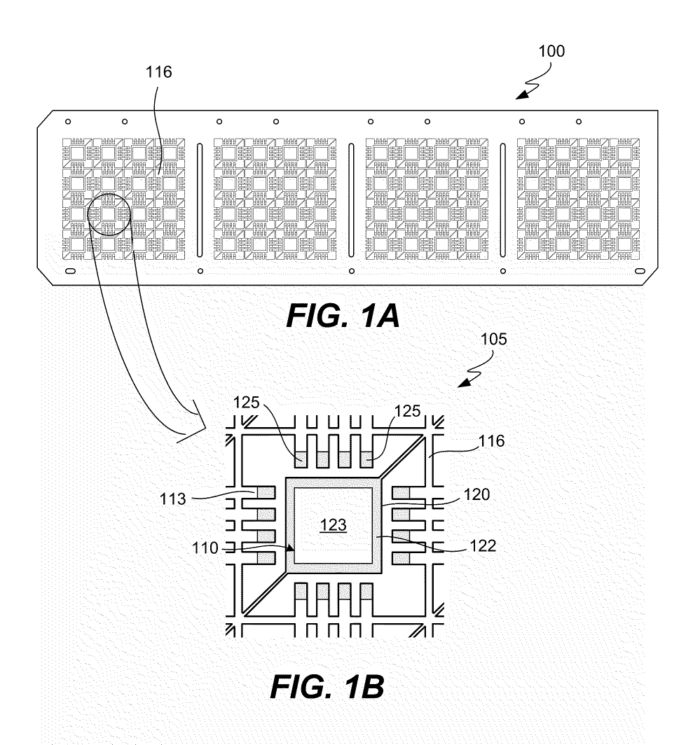

Referring initially to FIGS. 1(a) and 1(b), a lead frame panel 100 arranged in accordance with one embodiment of the invention will be described. As best seen in FIG. 1(a), lead frame panel 100 includes a multiplicity of device areas 105. The device areas are arranged in one or more two dimensional array on the panel, although a variety of other arrangements are possible (e.g. a one dimensional array, non-linear arrangements, etc.). In the illustrated embodiment, four two-dimensional arrays of device areas are shown. However it should be appreciated that more or fewer arrays may be provided. The lead frame panels are typically formed from copper or a copper based alloy, although other suitable materials (e.g., aluminum, may be used in various alternative embodiments).

The specific configuration of the device areas will vary in accordance with the needs of any particular package. By way of example, FIG. 1(b) illustrates one possible configuration of a device area 105 which takes a form suitable for use in packaging leadless lead frame (LLP) type packages (also known as QFN type packages). Although a LLP type package is shown, it should be appreciated that the invention may be used in conjunction with virtually any lead frame based package that utilizes down bonding or other wire bonding to a die attach pad or otherwise has reason to provide plating on regions of the die attach pad. By way of example, the described invention is well suited for use in SOIC, TSSOP, QFP, TO-220, and TO-263 type packages and a wide variety of other package styles.

Referring primarily to FIG. 1(b), each device area 105 includes a die attach pad 110 and a plurality of lead contacts 113. A matrix of tie bars (support bars) 116 is arranged to support the die attach pads 110 and the lead contacts 113. Selected portions of the top surface of the lead frame are plated with a conductive plating material 120 designed to improve bonding wire adhesion. When copper or a copper alloy is used to form the lead frame, the conductive plating is typically silver which adheres well to gold bonding wires. However, it should be appreciated that other suitable plating materials may be used in place of silver, so long as the plating material improves the adhesion of the bonding wires to the lead frame panel.

A portion, but not all, of the top surface of the die attach pad 110 is plated with the conductive plating material 120. The geometry of the plating on the die attach pad may vary widely in accordance with the needs of any particular design. The most important point being that plating should be present in regions of the die attach pad that will be down bonded to. In the illustrated embodiment, the conductive plating material on the die attach pad is arranged as a peripheral ring 122 that surrounds a non-plated central region 123 of the die attach pad. This plating geometry works well in many applications because it allows down bonding to any outer portion of the die attach pad. The plating 125 on the lead contacts 113 covers at least the regions of the lead contacts that are intended to serve as points of attachment for wire bonding.

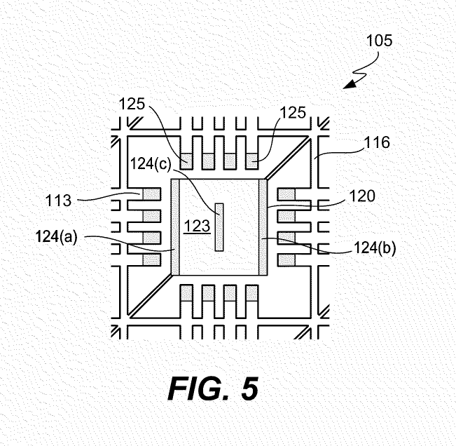

An alternative plating geometry is illustrated in FIG. 5. In this embodiment, silver bars 124 are plated on selected regions of the die attach pad instead of the peripheral ring 122. Such an arrangement is particularly appropriate for use in multi-chip modules (MCM) where multiple devices (e.g., ICs, passive components, etc.), are carried by and/or attached to a die attach pad. The bars may be located at peripheral edges of the die attach pad such as bars 124(a) and 124(b) and/or at other, more central locations (such as 124(c)) as may be appropriate for any particular package requirements. In still other embodiments, such as packages having dice that do not have ground I/O pads on all sides of the dice, it may be desirable to only plate peripheral edges of the die (e.g. using only peripheral bars 124(a) and 124(b). Peripheral bars can be located along part or all of one, two, three or all four side of the die attach pad. More centrally located patterns (e.g. bar 124(c)) can be positioned at any appropriate location on the die attach pad. It should be appreciated that the geometry of the plating is not limited to rectangular bars, rather any appropriate plating geometry may be used.

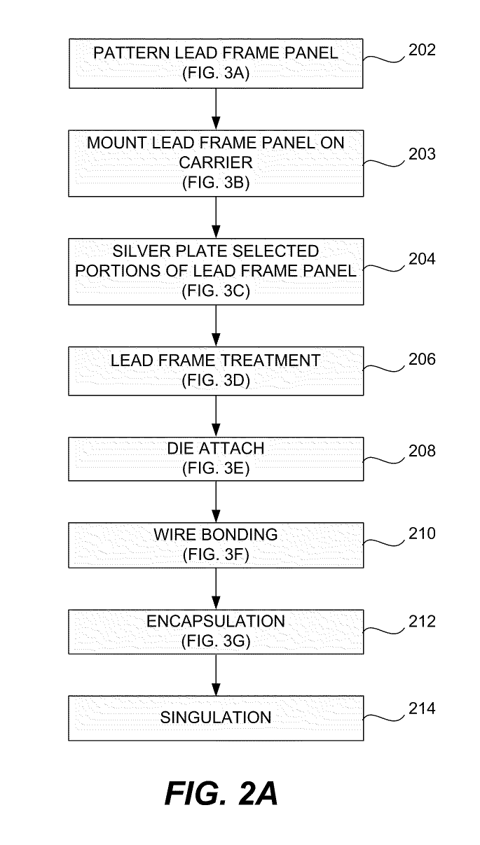

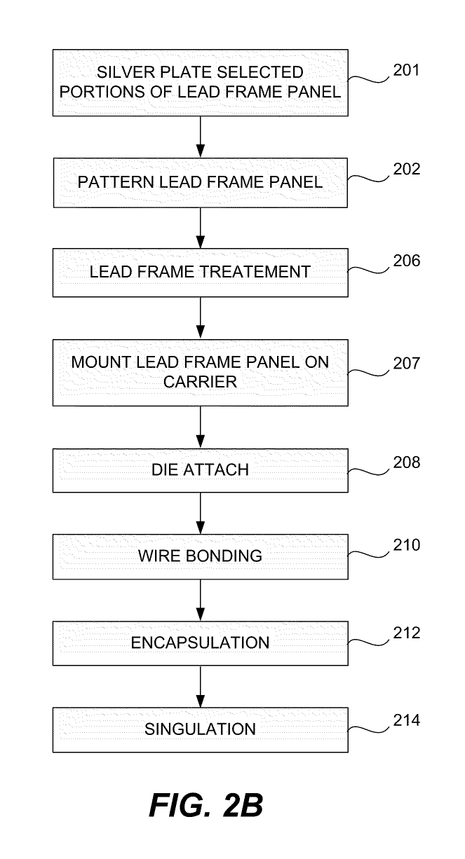

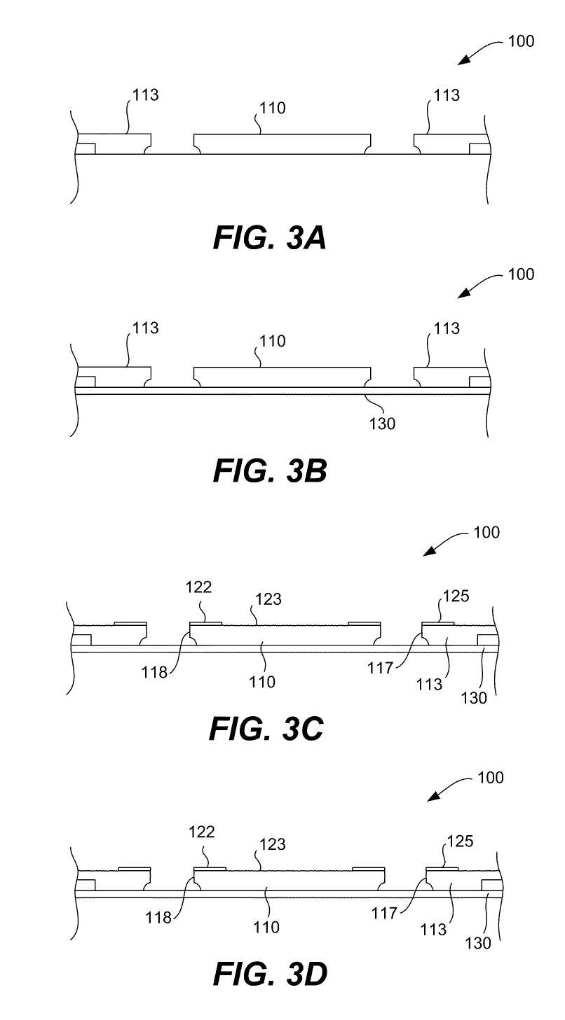

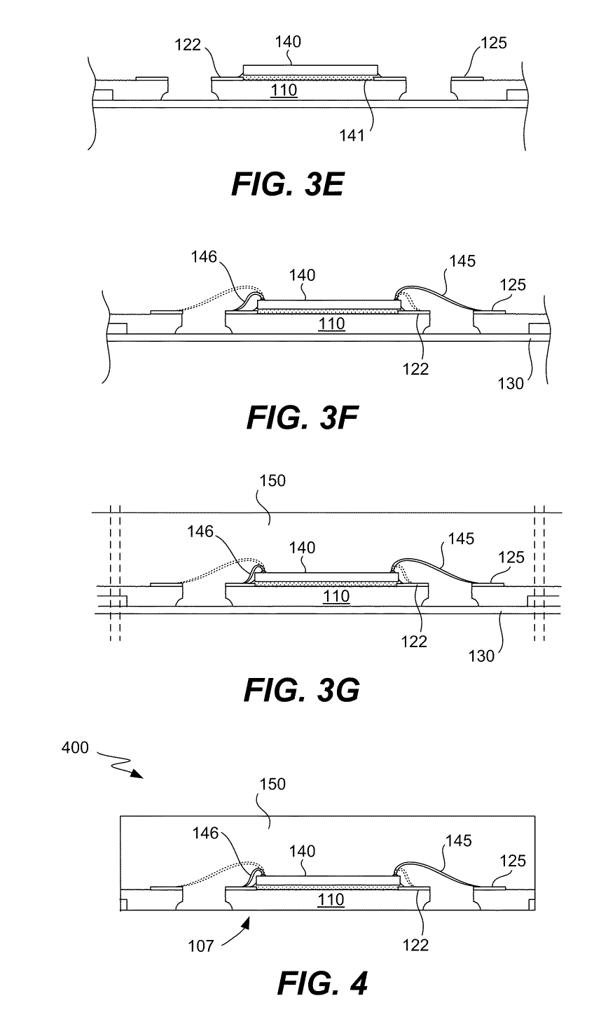

Several different plating processes may be used to plate the lead frame panel 100 illustrated in FIG. 1 and thereafter packaging integrated circuits utilizing the lead frame panel. One suitable process referred to herein as a mask plating process will be described in reference to the flow chart of FIG. 2(a) and the drawings of FIGS. 3(a)-3(g). A second plating process, referred to herein as a selective plating process will be described in reference to the flow chart of FIG. 2(b). Of course, a variety of other plating processes may be used as well.

Referring next to FIG. 2(a) and FIGS. 3(a)-3(g), the mask plating process will be described. In this embodiment, a lead frame panel 100 is initially patterned to define the leads/lead contacts 113, the die attach pad 110 and other features of the lead frame panel. (Step 202, FIG. 3(a)). The panel may be patterned using conventional techniques such as etching, stamping or a combination of the two.

After the lead frame panel has been patterned, the pattern lead frame is mounted on a carrier 130 (step 203, FIG. 3(b)). A variety of carriers may be used. In the illustrated embodiment, a carrier tape, as for example a polyimide based tae is used, although in alternative embodiments any other suitable carrier may be used.

Either before or after the carrier or has been applied, selected portions of the top surface of the lead frame are silver plated using conventional silver plating techniques. The silver plating material is applied to wire bonding landing regions of the lead contacts in a conventional manner (e.g. electroplating) to form lead plating 125. Simultaneously, portions, but not all of, the die attach pad are also plated to form die attach pad plating 122. (Step 204, FIG. 3(c)). In the embodiment illustrated in FIG. 3(c), the plating on the die attach pad is arranged as a peripheral ring that covers outer portions of the top surface of the die attach pad leaving a central region 123 of the die attach pad unplated. The peripheral ring is a useful geometry because the ring provides a down bonding region on all sides of the die attach pad. The ring geometry is easy to mask and may be used with virtually any die attached to die attach pad 110. Although a peripheral ring is useful in many implementations, it should be appreciated that many dice will not have ground bond pads on all sides of the die. In such implementations there may be no need to provide silver plating on all sides of the die attach pad. Accordingly, in alternative embodiments, the silver plating may be placed only in smaller regions of the die attach pad, as for example, along just one or two sides of the die attach pad, only along portions of one or more sides of the die attach pad in the specific area(s) that are to be down bonded to, or in any other desired geometry.

It should be appreciated that a variety of plating techniques may be used to plate the desired portions of the lead frame. In the illustrated embodiment, a mask (not shown) is used to cover portions of the top surface of the lead frame that are not to be plated. The mask may take any suitable form. By way of example, conventional mechanical masks (e.g., rubber stamps) work well for this purpose, although other appropriate masks may be used as well.

In the described embodiment, silver is used as the conductive plating material because the gold bonding wires adhere better to silver than the copper lead frame. Although silver is used in the described embodiment, it should be appreciated that the primary function of the conductive plating material is to improve the attachment of the bonding wires to the lead frame. Accordingly, in alternative embodiments, appropriate portions of the lead frame may be plated with other suitable conductors that improve the adhesion of the particular material used as the bonding wires to the specific material used as the lead frame.

After the lead frame has been silver plated, the lead frame is subjected to a lead frame treatment that “textures” or “roughens” exposed surfaces of the lead frame that are not silver plated. (Step 206, FIG. 3(d)). The exposed portions of the lead frame include the central region 123 of the die support surface of die attach pad 110, side edges 117 of the leads and side edges 118 of the die attach pad, and potentially portions of the top surfaces of the leads 113 that are not silver plated. In the illustrated embodiment, the lead frame treatment is performed with the carrier attached to the bottom surface of the lead frame so that the bottom surface of the lead frame is not exposed to the lead frame treatment and therefore is not roughened.

The roughened region(s) (e.g., central region 123) of the top surface of the die attach pad 110 improve adhesion of the die to the die attach pad when the die is subsequently attached to the die attach pad. The roughened side surfaces of the die attach pads and the leads help improve adhesion of the molding material to the lead frame when the die is subsequently encapsulated.

In some exposed die attach pad plastic molded package, it may not be desirable to roughen surfaces of the lead frame that are intended to be exposed and used as contacts because molding material may penetrate into vias in the textured surface during encapsulation thereby significantly reducing the electrical performance of the contact surface. However if the die attach pad is not exposed it may be acceptable and/or desirable to treat the bottom surface of the die attach pad so that the molding material adheres better to the die attach pad. In such embodiments, it may be desirable to forego attachment of the carrier 130 (step 203) or remove the carrier prior to the lead frame surface treatment. Similarly, if the surface treatment that is used is not prone to significant molding material penetration concerns, the surface treatment may readily be performed without the carrier 130 attached.

As will be appreciated by those familiar with the lead frame arts, there are several commercially available copper lead frame surface treatments that may be used to texture exposed portions of a lead frame. Preferably, a lead frame surface treatment that does not significantly attack the silver plating is selected. Therefore, the silver plating is not roughened or otherwise adversely affected by the treatment. Most commercially available lead frame treatments meet this requirement, so any of a variety of commercially available lead frame treatments may be utilized for lead frame treatment step 206. By way of example, the L1 surface treatment process marketed by Possehl Electronics, the Microetch process performed by Dynacraft or the copper oxide process performed by ASM are all suitable lead frame surface treatments that work well for the intended purpose.

After the lead fame treatment has been completed, the lead frame may be used to package integrated circuits using a variety of different packaging techniques. By way of example, a die 140 may be mounted on and adhesively secured to each die attach pad 110 in step 208 using conventional die attach techniques (FIG. 3(e)), e.g., using die attach adhesive 141. In the illustrated embodiment, the die 140 is centered on the die attach pad 110 so that silver plating is exposed on each side of the die. However, in alternative embodiments, the die does not need to be centered relative to the die attach pad. The width of the silver plating strip may optionally be chosen such that the die does not overlie the silver plating. Such an arrangement has the advantage of providing the strongest die attachment because the adhesive used to mount the die will not stick as well to the silver plating as it does to the roughened copper surface 123. However, this is not a requirement and in various embodiments, the die may partially overlie some of the silver plating (preferably only a relatively small amount of the silver plating). In practice, allowing some small overlap is sometimes desirable because it allows the use of more flexible tolerances when applying the conductive plating material.

After the die 140 has been attached to the die attach pad 110, it may be electrically connected to the lead frame using conventional wire bonding techniques. (Step 210). Typically one end of each bonding wire is attached to an associated bond pad 141 on the die and a second end of each bonding wire is attached to a silver plated portion 120 of the lead frame as illustrated in FIG. 3(f). Typically, most of the bonding wires, designated 145 in FIG. 3(f) are each connected to an associated lead 116. However, at least one (and often more than one) of the bonding wires (designated 146 in FIG. 3(f)) are down bonded to the silver plated portion 122 of the die attach pad. Usually the ground I/O pads on the die are down bonded to the die attach pad so that the die attach pad becomes a ground contact for the final package. However, this is not a requirement so in other embodiments, the die attach pad could be a power contact, or even potentially a signal contact.

After the dice have been attached and wire bonded to the lead frame, the dice and bonding wires together with portions of the lead frame may be encapsulated in step 212 using conventional encapsulation techniques such as plastic molding, as shown in FIG. 3(g). The illustrated embodiment is a LLP type package, so the bottom surfaces of the lead contacts 116 and the bottom surface of the die attach pad 113 are intended to remain exposed. In the illustrated embodiment, the carrier tape 130 remains adhered to the bottom surface of the lead frame panel 100 throughout the packaging process, including the encapsulation. Therefore, the carrier tape prevents molding material from covering the contacts during the encapsulation process.

After encapsulation and any other desired panel level processing, the panel may be singulated in step 214 to form individual semiconductor packages. The singulation may be arranged to sacrifice the tie bars 116. A singulated package is diagrammatically illustrated in FIG. 4.

An alternative plating process is illustrated in FIG. 2(b). In this embodiment selective portions of a blank (unpatterned) lead frame strip or panel are initially silver plated (step 201). The plating is patterned in a manner that provides plating in the region where plating is desired and leaves other portions of the lead frame exposed. As with the previously described process, any suitable mask, as for example a photoresist based mask, may be used to accomplish the selective plating.

After the lead frame blank has been selectively plated, the lead frame is patterned (step 202) to define the desired features of the lead frames (e.g., leads, contacts, die attach pads, etc.). As discussed above, any suitable technique, as for example, stamping or etching may be used to pattern the lead frame. After patterning, the entire lead frame panel may be subjected to a lead frame treatment (step 206). Either before or after, the lead frame treatment, the lead frame panel may be mounted on an appropriate carrier (step 207). In the embodiment illustrated in FIG. 2(b), the carrier is attached after lead frame treatment, although as previously discussed, in alternative embodiments, the carrier may be applied prior to the lead frame treatment and there may be good reasons to do so.

After the lead frame treatment and carrier attachment, the packaging process of FIG. 2(b) may take a flow similar to that described above with respect to FIG. 2(a).

A representative singulated package formed in accordance with the either of the described processes is illustrated in FIG. 4. As seen therein, the package 400 includes a lead frame 107 having a die attach pad 110 and a plurality of lead contacts 113. A conductive plating ring 122 covers a peripheral surface of the top surface of the die attach pad. Portions of the top surface of the lead contacts 113 are also silver plated. A plurality of bonding wires 145 electrically connect selected bond pads on die 140 to associated lead contacts 113 and one or more down bonded bonding wires 146 are down bonded from the die 140 to die attach pad 110 to electrically connect ground bond pads on the die to the die attach pad. The die, the bonding wires 145, 146 and portions of lead frame 107 are encapsulated in a plastic encapsulant 150 leaving bottom contact surfaces of the lead contacts and die attach pad exposed to facilitate electrical connection to external devices.

In the embodiments described above, down bond failures are substantially reduced primarily due to the fact that the surface treatment of much of the die support surface of the die attach pad 110 (e.g., roughened central region 123) significantly reduces the probability of die attach pad delamination, which is believed to be the primary cause of down bond failure. If desired, additional efforts may also be made to improve the adhesion of the down bonded bonding wires 146 to the die attach pad 110. For example, the ground I/O pads on the die 140 may be coupled to the grounded die attach pad 110 using a reverse ball bond with wedge stitched on ball (RBSOB) technique. In this approach, a wire bonding bump is initially created on the appropriate ground I/O pad on the die 140. The bump is made by using a standard wire bonding capillary to ultrasonically deposit a ball bond onto the selected bond pad. Rather than continuing the extrusion of the wire, the capillary truncates the wire near the top of the ball bond, such that only a wire bonding “ball” or “bump” remains atop the bond pad.

A reverse wire bond is then used to electrically couple the ground I/O pad to the die attach pad. During the wire bonding process, a second ball bond is formed on the die attach pad, and a stitch bond is formed on top of the bump on the ground I/O pad. With this arrangement, the down bonding wires are electrically coupled to the ground I/O pad via a stitch bond located atop the bump. The height of the bumps may vary in accordance with the needs of a particular embodiment. By way of example, in some embodiments, a bump having a height that is approximately one-third the height of a conventional ball bond works well. The described reverse wire bonding with stitch on ball technique improves the adhesion of the ground bonding wire to the lead frame. This is because the ball bond adheres to the silver-plated portion of the die attach pad better than a stitch bond would.

Although only a few embodiments of the invention have been described in detail, it should be appreciated that the invention may be implemented in many other forms without departing from the spirit or scope of the invention. Although the formation of an LLP type package has been illustrated, it should be appreciated that the invention can be used with any package that incorporates down bonding to a die attach pad. Further, although specific steps and a specific order were articulated in describing the illustrated embodiments, it should be appreciated that in many instances, the specific steps used as well as their order may be varied without departing from the scope of the invention.

It is believed that in many applications the described die attach pad surface treatment technique will adequately eliminate delamination problems between the die and the die attach pad so that no further processes will be needed to improve down bond reliability. However, when desired, in addition to the stitch on ball technique described above, other complementary techniques down bond enhancement techniques can be employed in parallel with the described approaches to further improve down bond reliability. Therefore, the present embodiments should be considered illustrative and not restrictive and the invention is not to be limited to the details given herein, but may be modified within the scope of the appended claims.

What is claimed is:

1. An integrated circuit package comprising:
a lead frame including a die attach pad and a plurality of leads that are physically and electrically isolated from the die attach pad, the die attach pad including a die support surface, wherein a first portion of the die support surface is plated with a conductive plating material and a second portion of the die support surface is roughened;
a die attached to the die support surface of the die attach pad, the die having a multiplicity of bond pads, wherein the roughened second portion of the die support surface is arranged to improve the adhesion of the die to the die support surface;
a first set of bonding wires, wherein each bonding wire in the first set of bonding wires has a first end attached to an associated bond pad and a second end attached to an associated lead to thereby electrically connect the associated bond pad to the associated lead; and
at least one down bonding wire, wherein each down bonding wire has a first end attached to an associated bonding pad and a second end attached to the conductive plating on the die attach pad.

2. An integrated circuit package as recited in claim 1 further comprising a plastic encapsulant that encapsulates the die, the bonding wires and at least portions of the lead frame while leaving a contact surface of the die attach pad exposed to facilitate electrically coupling the die attach pad to an electrical contact.

3. An integrated circuit package as recited in claim 2 wherein the die attach pad is electrically connected to ground.

4. An integrated circuit package as recited in claim 1, wherein the conductive plating is arranged as a ring that surrounds the roughened second portion of the die support surface.

5. An integrated circuit package as recited in claim 4, wherein the plating is a silver based plating and the bonding wires are formed from gold.

6. An integrated circuit package as recited in claim 1 wherein a plurality of down bonding wires are coupled to the conductive plating on the die attach pad.

7. An integrated circuit package as recited in claim 1 wherein:
the lead fame is formed from copper or a copper based alloy;
the leads are lead contacts each having an associated wire bonding surface and an opposing contact surface;
the conductive plating is a silver plating and the silver plating on the die attach pad defines a silver plating ring that covers peripheral portions of the die attach surface, and wherein silver plating is further provided on at least a portion of the wire bonding surface of each lead; and
the silver plating ring has a central opening that exposes a central portion of the die support surface, wherein the central portion of the die support surface and side portions of the die attach pad and lead contacts are roughened and wherein a contact surface of the die attach pad located opposite the die support surface is not roughened and the contact surfaces of the lead contacts are not roughened.

8. An integrated circuit package as recited in claim 7 further comprising a plastic encapsulant that encapsulates the die, the bonding wires and at least portions of the lead frame, while leaving the contact surfaces of the lead contacts exposed on a bottom surface of the package and leaving a contact surface of the die attach pad exposed on a bottom surface of the package.

9. A method of packaging an integrated circuit using a conductive lead frame that includes a die attach pad, the method comprising:
adhering a carrier to a bottom surface of the lead frame;
plating selected portions of a top surface of the lead frame with a conductive plating material, wherein the plated portions of the lead frame include a portion but not all of a die support surface of the die attach pad;
exposing the plated lead frame to a lead frame treatment with the carrier adhered to the bottom surface of the lead frame to roughen exposed portions of the lead frame that are not plated including the portions of the die support surface that are not plated, wherein the lead frame treatment does not substantially roughen the plated regions;
attaching a die to the die support surface of the die attach pad, the die having a multiplicity of bond pads, wherein the roughened portion of the die support surface is arranged to improve the adhesion of the die to the die support surface;
electrically coupling the die to at least some of the leads; and
wire bonding at least one of the bond pads on the die to the plated portion of the die attach pad.

10. A method as recited in claim 9 wherein:
the lead fame if formed from copper or a copper based alloy;
the bonding wires are formed from gold; and
the conductive plating is a silver plating.

11. A method as recited in claim 10 wherein the silver plating on the die attach pad is arranged as a ring that surrounds a roughened second portion of the die support surface.

12. An method as recited in claim 9 further comprising encapsulating the die, the bonding wires and at least portions of the lead frame with a plastic encapsulant material while leaving a contact surface of the die attach pad exposed to facilitate electrically coupling the die attach pad to an electrical contact.

13. A method as recited in claim 9 wherein the plating on the die attach pad is arranged as a ring that surrounds the roughened second portion of the die support surface.

14. A method of using an integrated circuit package formed as recited in claim 9 comprising mounting the packaged integrate circuit on a substrate board having electrical interconnects thereon, wherein the packaged integrated circuit is mounted in a manner that electrically connects the die attach pad and at least some of the leads to the board.

15. A method as recited in claim 14 wherein the die attach pad is electrically connected to ground.

16. A method as recited in claim 9 wherein a plurality of bonding wires are down wired bonded to the die attach pad.

17. A method as recited in claim 9 wherein:
the lead fame is formed from copper or a copper based alloy;
the bonding wires are formed from gold;
the leads are lead contacts each having an associated wire bonding surface and an opposing contact surface;
the conductive plating is a silver plating and the silver plating on the die attach pad defines a silver plating ring that covers peripheral portions of the die attach surface, and wherein silver plating is further provided on at least a portion of the wire bonding surface of each lead; and
the silver plating ring has a central opening that exposes a central portion of the die support surface, wherein the central portion of the die support surface and side portions of the die attach pad and lead contacts are roughened during the lead frame treatment and wherein the contact surfaces of the lead contacts and the bottom surface of the die attach pad are not roughened.

18. A method of preparing a conductive lead frame panel for use in packaging integrated circuits, the lead frame panel having a multiplicity of device areas defined thereon, each device area including a plurality of leads and a die attach pad, the method comprising:
adhering a carrier to a bottom surface of the lead frame panel;
silver plating selected portions of a top surface of the lead frame panel, wherein the silver plated portions of each device area defined in the lead frame panel include a portion of a die support surface of the die attach pad;
exposing the silver plated lead frame panel to a lead frame treatment with the carrier adhered to the bottom surface of the lead frame panel to roughen exposed portions of the lead frame panel that are not silver plated, wherein the lead frame treatment does not substantially roughen the silver plated regions of the lead frame panel.

19. A method as recited in claim 18 wherein the silver plated portion of each of the die attach pads defines a silver plating ring that covers peripheral portions of the associated die support surface while exposing a central portion of the associated die support surface, wherein the central portion of the die support surface and side portions of the die attach pad and lead contacts are roughened during the lead frame treatment and wherein the contact surfaces of the lead contacts and the bottom surface of the die attach pad are not roughened during the lead frame treatment.

20. A method as recited in claim 19 wherein silver plating is further provided on at least a portion of a wire bonding surface of each lead.
